(19) United States
(12) Patent Application Publication
(10) Pub. No.: US 2025/0376486 A1
(43) Pub. Date: Dec. 11, 2025

(54) NOVEL MOLYBDENUM COMPOUND, METHOD OF PRODUCING THE SAME, AND METHOD OF PRODUCING MOLYBDENUM-CONTAINING THIN FILM INCLUDING THE SAME

(71) Applicant: Versum Materials Korea Inc., Siheung-Si (KR)

(72) Inventors: Mi-Jeong Han, Daejeon (KR); Kang Yong Lee, Daejeon (KR); Young Jin Kim, Daejeon (KR); Jin Mook Lim, Daejeon (KR); Han Sang Song, Seongnam-Si (KR)

(21) Appl. No.: 18/877,039

(22) PCT Filed: Jul. 18, 2023
(86) PCT No.: PCT/KR2023/010314

§ 371 Date: Dec. 19, 2024

(30) Foreign Application Priority Data
Jul. 20, 2022 (KR) 10-2022-0089321

(51) Int. Cl. C07F 11/00; C23C 16/46; H01L 21/3205

(52) U.S. Cl. CPC C07F 11/00; C23C 16/46; H01L 21/32051

(57) ABSTRACT

Provided are a molybdenum compound. a method of producing the same. and a method of producing a molybdenum-containing thin film including the compound, and since the novel molybdenum compound shows excellent thermal stability and vapor pressure properties. a thin film using the same may show uniform and excellent electrical properties.

### TECHNICAL FIELD

The present invention relates to a molybdenum compound, a method of producing the same, and a method of producing a molybdenum-containing thin film including the same.

### BACKGROUND ART

In the semiconductor device fields, various thin film deposition methods have been developed and applied, and these may be, for example, chemical vapor deposition (CVD), atomic layer deposition (ALD), plasma enhanced chemical vapor deposition (PECVD), plasma enhanced atomic layer deposition (PEALD), and the like.

In a chemical vapor deposition process, a volatile metal precursor form including a metal such as tungsten and ruthenium is adsorbed on a substrate, and then reacted or decomposed on the surface thereof to produce a deposit.

In an atomic layer deposition process, reactants are supplied in an intermittent step and are decomposed by their chemical exchange to form a thin film containing a metal. The atomic layer deposition may be performed at a temperature lower than that of the chemical vapor deposition and has an advantage in processing as well as in forming a thin film.

In addition, a plasma enhanced atomic layer deposition process provides a reactant in a plasma form on the surface of a substrate so that growth of a layer is promoted. In general, a plasma enhanced atomic layer deposition system includes a plasma source and an optional gas flow regulator with a RF power supply.

Along with the development of various thin film deposition methods as described above, a very important part is a precursor including a metal. Since the thin film grows with the chemical reaction of the metal precursor, it is very important to develop a metal precursor which may show more improved performance.

That is, the metal precursor needs sufficient vapor pressure so that the metal precursor is easily transported from a gaseous precursor-containing container to a reaction chamber, is required to have long-term thermal stability in a storage and transportation process, and needs thermal stability in a gas state in order to control impurities of the formed thin film. In addition, the metal precursor should show excellent reactivity to reaction gas in order to be easily formed into a thin film on a substrate.

Meanwhile, a molybdenum-containing thin film has low resistance, a large work function, and excellent thermal stability and chemical stability and is being used in a wide range of fields such as solar cells, field emission displays, liquid displays, plasma display panels, organic light-emitting devices, and semiconductors. However, a study of a molybdenum precursor which may be easily applied to various deposition methods showing improved performance is still needed.

### RELATED ART DOCUMENTS

### Patent Documents

(Patent Document 1) Korean Patent Laid-Open Publication No. 10-2021-0024421 A

(Patent Document 2) Korean Patent Laid-Open Publication No. 10-2021-0024418 A

### DISCLOSURE OF INVENTION

### Technical Problem

An object of the present invention is to provide a molybdenum compound which may be useful as a molybdenum-containing precursor for thin film deposition having excellent thermal stability and volatility.

### Solution to Problem

In one general aspect, a molybdenum compound represented by the following Chemical Formula 1 is provided:

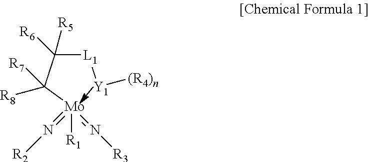

wherein
L₁ is C1-C5 alkylene;
Y₁ is N, O, or S;
R₁ is halogen, C1-C7 alkyl, C1-C7 alkoxy, mono C1-C7 alkylamino, or di C1-C7 alkylamino;
R₂ and R₃ are each independently C1-C7 alkyl;
R₄ to R₈ are each independently hydrogen or C1-C7 alkyl; and
n is 1 or 2.

In Chemical Formula 1, L may be C1-C3 alkylene, Y₁ may be N, O, or S, R₁ may be halogen, C1-C5 alkyl, or C1-C5 alkoxy, R₂ and R₃ may be each independently C1-C5 alkyl, R₄ to R₈ may be each independently hydrogen or C1-C5 alkyl, and n may be 1 or 2.

In addition, in Chemical Formula 1, L₁ may be C1-C3 alkylene, Y₁ may be N or O, R₁ may be halogen, C1-C5 alkyl, or C1-C5 alkoxy, R₂ and R₃ may be each independently branched C3-C5 alkyl, R₄ to R₈ may be each independently hydrogen or linear C1-C3 alkyl, and n may be 1 or 2.

The molybdenum compound according to an exemplary embodiment of the present invention may be represented by the following Chemical Formula 2:

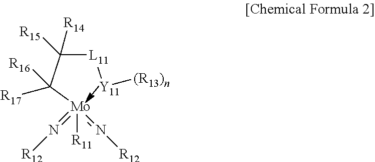

wherein
L₁₁ is C1-C5 alkylene;
Y₁₁ is N, O, or S;
R₁₁ is halogen, C1-C7 alkyl, C1-C7 alkoxy, monoC1-C7 alkylamino, or diC1-C7 alkylamino;
R₁₂ is C1-C7alkyl;
R₁₃ to R₁₇ are each independently hydrogen or C1-C7 alkyl; and

n is 1 or 2.

In Chemical Formula 2, L₁₁ may be C1-C3 alkylene, Y₁₁ may be N or O, R₁₁ may be halogen, C1-C5 alkyl, or C1-C5 alkoxy, R₁₂ may be branched C3-C5 alkyl, R₁₃ to R₁₇ may be each independently hydrogen or linear C1-C3 alkyl, and n may be 1 or 2.

The molybdenum compound according to an exemplary embodiment of the present invention may be selected from the following compounds:

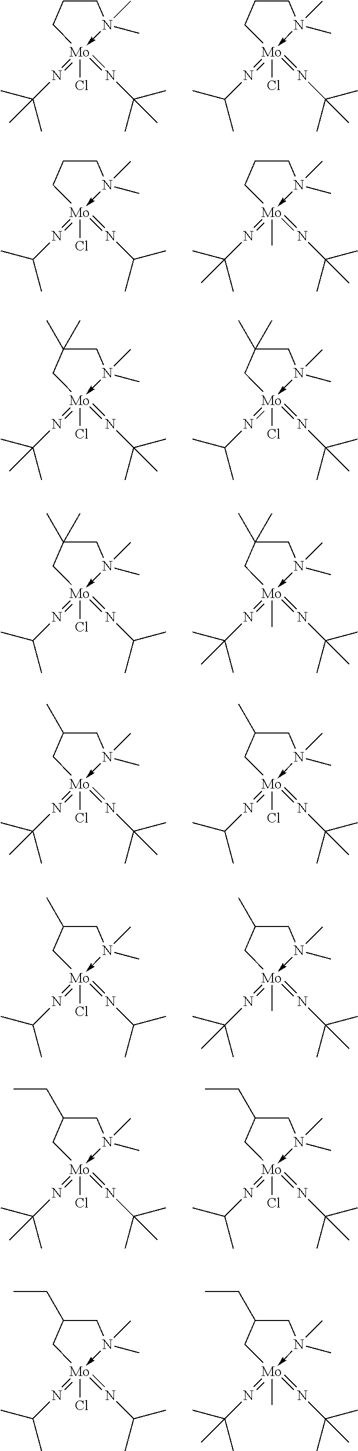

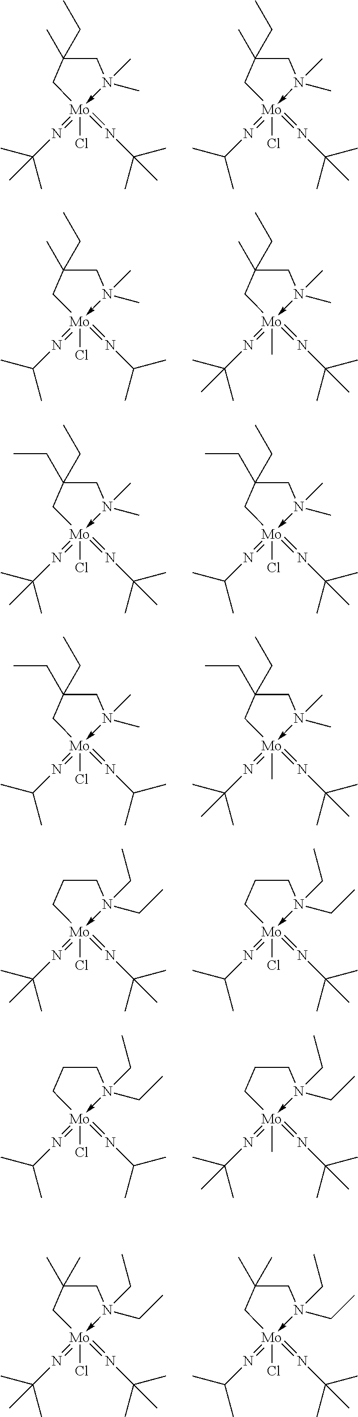

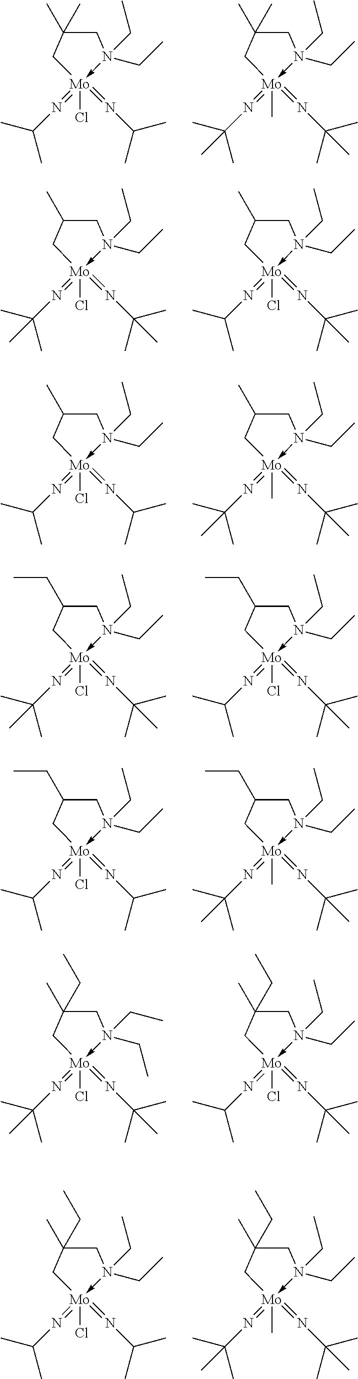

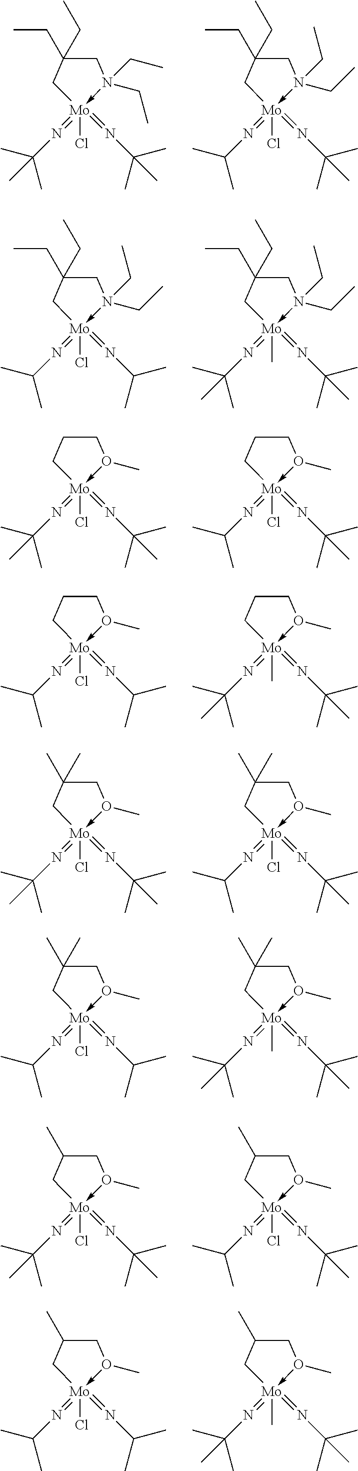

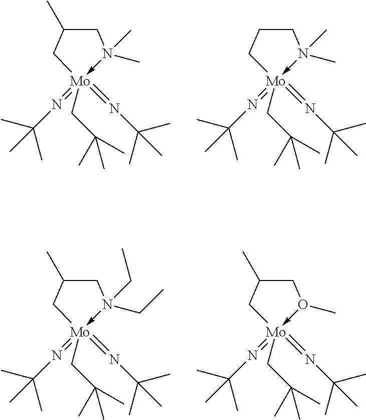

In another general aspect, a method of producing a novel molybdenum compound includes: reacting a compound represented by the following Chemical Formula 11 and a compound represented by the following Chemical Formula 12 to produce a molybdenum compound represented by the following Chemical Formula 1:

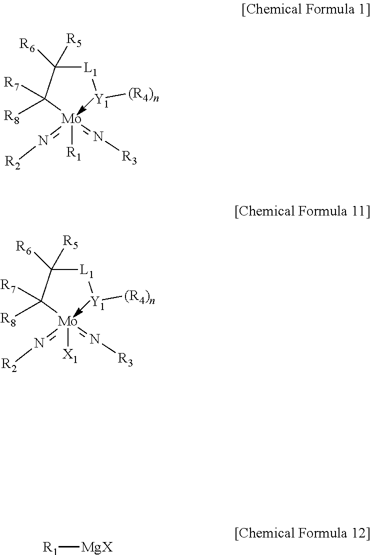

wherein
L₁ is C1-C5 alkylene;
Y₁ is N, O, or S;
R₁ is halogen, C1-C7 alkyl, C1-C7 alkoxy, monoC1-C7 alkylamino, or diC1-C7 alkylamino;
R₂ and R₃ are each independently C1-C7 alkyl;
R₄ to R₈ are each independently hydrogen or C1-C7 alkyl;
X and X₁ are each independently halogen; and
n is 1 or 2.

In addition, the method of producing a molybdenum compound according to an exemplary embodiment of the present invention may includes: reacting a compound represented by the following Chemical Formula 13 and a compound represented by the following Chemical Formula 14 to produce the compound represented by Chemical Formula 11:

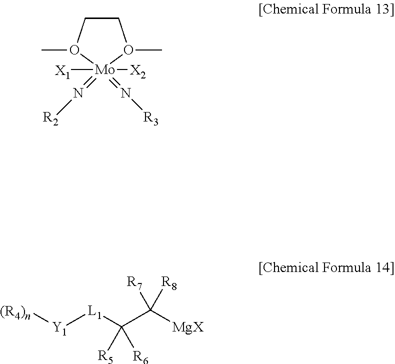

wherein
L₁ is C1-C5 alkylene;
Y₁ is N, O, or S;
R₂ and R₃ are each independently C1-C7 alkyl;
R₄ to R₈ are each independently hydrogen or C1-C7 alkyl; and
X, X₁, and X₂ are each independently halogen; and
n is 1 or 2.

In another general aspect, a molybdenum-containing composition for thin film deposition includes the molybdenum compound according to an exemplary embodiment of the present invention.

In another general aspect, a method of producing a molybdenum-containing thin film includes: a) heating a substrate mounted in a chamber; and b) injecting a reaction gas and the molybdenum-containing composition for thin film deposition according to an exemplary embodiment of the present invention into the chamber to produce a molybdenum-containing thin film, wherein a temperature of the substrate may be maintained at 300 to 700° C.

In still another general aspect, a molybdenum-containing thin film produced by using the molybdenum compound according to an exemplary embodiment of the present invention is provided.

### Advantageous Effects of Invention

The novel molybdenum compound of the present invention shows excellent thermal stability and vapor pressure properties and may be useful as a precursor for a molybdenum-containing thin film deposition.

The molybdenum-containing thin film produced by using the novel molybdenum compound of the present invention as a precursor may show uniform and significantly improved electrical properties.

### BRIEF DESCRIPTION OF DRAWINGS

FIG. 1 is a drawing showing the results of TGA analysis of Examples 1 to 3.

FIG. 2 is a drawing showing the results of analyzing vapor pressures of Examples 1 to 3.

### BEST MODE FOR CARRYING OUT THE INVENTION

Hereinafter, the molybdenum compound of the present invention, a method of producing the same, and a method of producing a molybdenum-containing thin film including the same will be described in detail.

The singular form used in the present invention may be intended to also include a plural form, unless otherwise indicated in the context.

In addition, the numerical range used in the present invention includes all values within the range including the lower limit and the upper limit, increments logically derived in a form and span in a defined range, all double limited values, and all possible combinations of the upper limit and the lower limit in the numerical range defined in different forms. Unless otherwise defined in the specification of the present invention, values which may be outside a numerical range due to experimental error or rounding off of a value are also included in the defined numerical range.

The term “comprise” described in the present invention is an open-ended description having a meaning equivalent to the term such as “is/are provided”, “contain”, “have”, or “is/are characterized”, and does not exclude elements, materials or processes which are not further listed.

Hereinafter, the present invention will be described in detail. Technical terms and scientific terms used herein have the general meaning understood by those skilled in the art to which the present invention pertains unless otherwise defined, and a description for the known function and configuration which may unnecessarily obscure the gist of the present disclosure will be omitted in the following description.

“Alkyl” described in the present invention refers to a saturated linear or branched acyclic hydrocarbon having 1 to 7, preferably 1 to 5, and more preferably 1 to 3 carbon atoms. Representative saturated linear alkyl includes methyl, ethyl, n-propyl, n-butyl, n-pentyl, n-hexyl, and n-heptyl, while a saturated branched alkyl includes isopropyl, sec-butyl, isobutyl, tert-butyl, isopentyl, 2-methylhexyl, 3-methylbutyl, 2-methylpentyl, 3-methylpentyl, 4-methylpentyl, 2-methylhexyl, 3-methylhexyl, 2-methylpentyl, 3-methylpentyl, 4-methylpentyl, 2-methylhexyl, 3-methylhexyl, 4-methylhexyl, 5-methylhexyl, 2,3-dimethylbutyl, 2,3-dimethylpentyl, 2,4-dimethylpentyl, 2,3-dimethylhexyl, 2,4-dimethylhexyl, 2,5-dimethylhexyl, 2,2-dimethylpentyl, 2,2-dimethylhexyl, 3,3-dimethylpentyl, 3,3-dimethylhexyl, 4,4-dimethylhexyl, 2-ethylpentyl, 3-ethylpentyl, 2-ethylhexyl, 3-ethylhexyl, 4-ethylhexyl, 2-methyl-2-ethylpentyl, 2-methyl-3-ethylpentyl, 2-methyl-4-ethylpentyl, 2-methyl-2-ethylhexyl, 2-methyl-3-ethylhexyl, 2-methyl-4-ethylhexyl, 2,2-diethylpentyl, 3,3-diethylhexyl, 2,2-diethylhexyl, and 3,3-diethylhexyl.

The term “alkoxy” described in the present invention refers to —O-(alkyl) including —OCH₃, —OCH₂CH₃, —O(CH₂)₂CH₃, —O(CH₂)₃CH₃, —O(CH₂)₄CH₃, —O(CH₂)₅CH₃, and the like, in which the definition of “alkyl” follows the above definition.

“Mono-alkylamino” described in the present invention refers to —NH(alkyl) including —NHCH₃, —NHCH₂CH₃, —NH(CH₂)₂CH₃, —NH(CH₂)₃CH₃, —NH(CH₂)₄CH₃, —NH(CH₂)₅CH₃, and the like, in which the definition of “alkyl” follows the above definition.

“Di-alkylamino” described in the present invention refers to-N (alkyl) (alkyl) including —N(CH₃)₂, —N(CH₂CH₃)₂, —N((CH₂)₂CH₃)₂, —N(CH₃)(CH₂CH₃), and the like, in which the definition of each “alkyl” independently follows the above definition.

“Halogen” described in the present invention refers to fluorine, chlorine, bromine, or an iodine atom.

“Alkylene” described in the present invention refers to a divalent organic radical derived by removing one hydrogen from “alkyl”, in which the definition of “alkyl” follows the above definition.

The number of carbons described in the present invention does not include the number of carbons of substituents, and as an example, C1-C7 alkyl refers to alkyl having 1 to 7 carbon atoms which does not include the number of carbons of the substituents of the alkyl.

The present invention provides a molybdenum compound represented by the following Chemical Formula 1 having improved vapor pressure and excellent thermal stability:

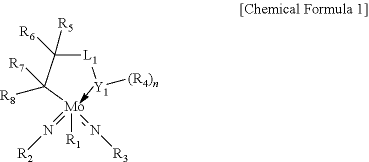

wherein
L₁ is C1-C5 alkylene;
Y₁ is N, O, or S;
R₁ is halogen, C1-C7 alkyl, C1-C7 alkoxy, monoC1-C7 alkylamino, or diC1-C7alkylamino;
R₂ and R₃ are each independently C1-C7 alkyl;
R₄ to R₈ are each independently hydrogen or C1-C7 alkyl; and
n is 1 or 2.

The novel molybdenum compound represented by Chemical Formula 1 of the present invention includes two imide groups (═N—) to improve thermal stability and vapor pressure and improve reactivity. Therefore, a molybdenum-containing thin film using the compound may show more uniform and high quality.

In Chemical Formula 1, L₁ may be C1-C3 alkylene, Y₁ may be N, O, or S, R₁ may be halogen, C1-C5 alkyl, or C1-C5 alkoxy, R₂ and R₃ may be each independently C1-C5 alkyl, R₄ to R₈ may be each independently hydrogen or C1-C5 alkyl, and n may be 1 or 2.

In addition, in Chemical Formula 1, L₁ may be C1-C3 alkylene, Y₁ may be N or O, R₁ may be halogen, C1-C5 alkyl, or C1-C5 alkoxy, R₂ and R₃ may be each independently branched C3-C5 alkyl, R₄ to R₈ may be each independently hydrogen or linear C1-C3 alkyl, and n may be 1 or 2.

The molybdenum compound according to an exemplary embodiment of the present invention may be represented by the following Chemical Formula 2:

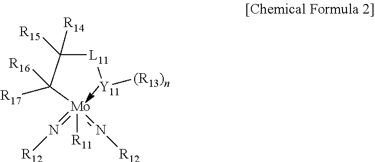

wherein
L₁₁ is C1-C5 alkylene;
Y₁₁ is N, O, or S;
R₁₁ is halogen, C1-C7 alkyl, C1-C7 alkoxy, monoC1-C7 alkylamino, or diC1-C7 alkylamino;
R₁₂ is C1-C7alkyl;
R₁₃ to R₁₇ are each independently hydrogen or C1-C7 alkyl; and
n is 1 or 2.

In Chemical Formula 2, L₁₁ may be C1-C3 alkylene, Y₁₁ may be N or O, R₁₁ may be halogen, C1-C5 alkyl, or C1-C5 alkoxy, R₁₂ may be branched C3-C5 alkyl, R₁₃ to R₁₇ may be each independently hydrogen or linear C1-C3 alkyl, and n may be 1 or 2.

In addition, the molybdenum compound according to an exemplary embodiment of the present invention may be represented by the following Chemical Formula 3:

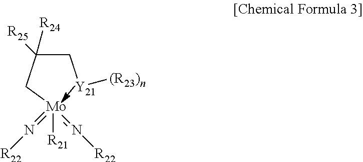

wherein
Y₂₁ is N, O, or S;
R₂₁ is halogen, C1-C7 alkyl, C1-C7 alkoxy, monoC1-C7 alkylamino, or diC1-C7 alkylamino;
R₂₂ is C1-C7alkyl;
R₂₃ to R₂₅ are each independently hydrogen or C1-C7 alkyl; and
n is 1 or 2.

Specifically, in Chemical Formula 3, Y₂₁ may be Nor O, R₂₁ may be halogen, C1-C5 alkyl, or C1-C5 alkoxy, R₂₂ may be branched C3-C5 alkyl, R₂₃ to R₂₅ may be each independently hydrogen or linear C1-C3 alkyl, and n may be 1 or 2.

More specifically, in Chemical Formula 3 of the molybdenum compound according to an exemplary embodiment of the present invention, Y₂₁ may be N or O, R₂₁ may be halogen or C1-C5 alkyl, R₂₂ may be branched C3-C5 alkyl, R₂₃ to R₂₅ may be each independently hydrogen, methyl, or ethyl, and n may be 1 or 2.

The molybdenum compound according to an exemplary embodiment of the present invention may be selected from the following compounds:

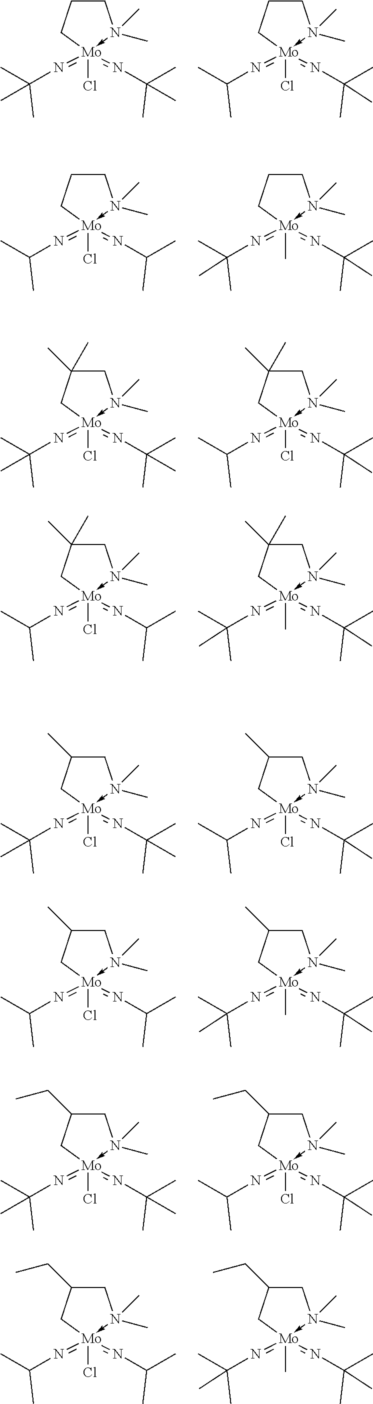

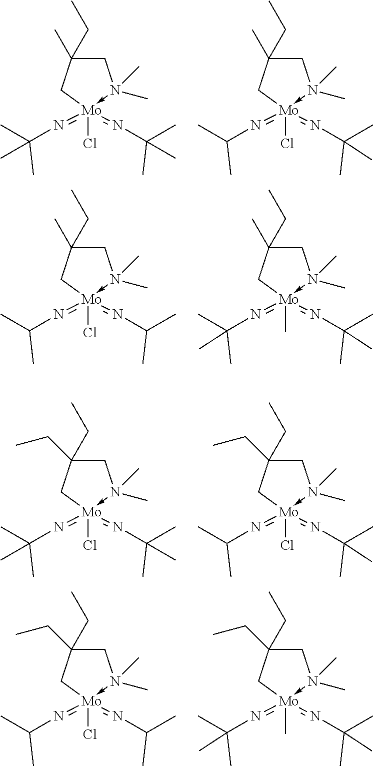

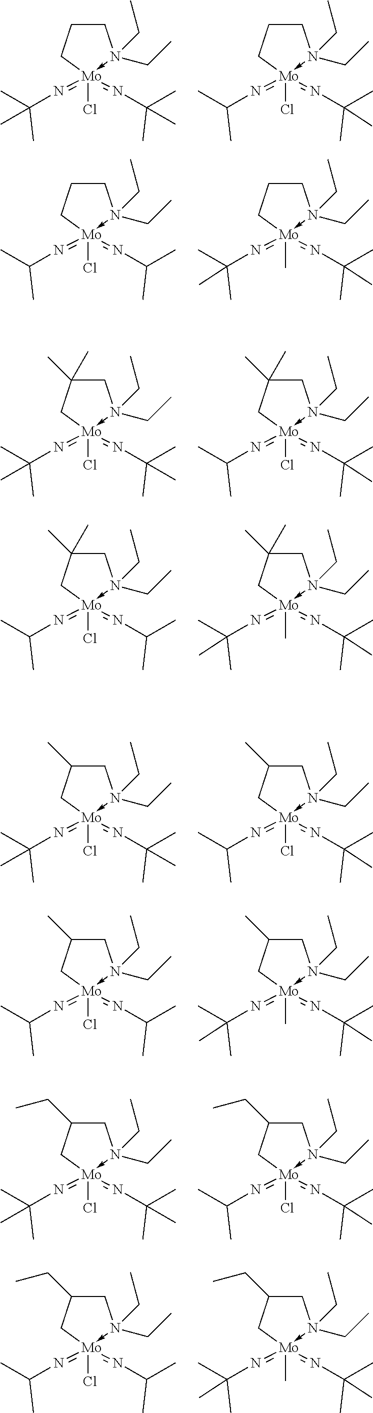

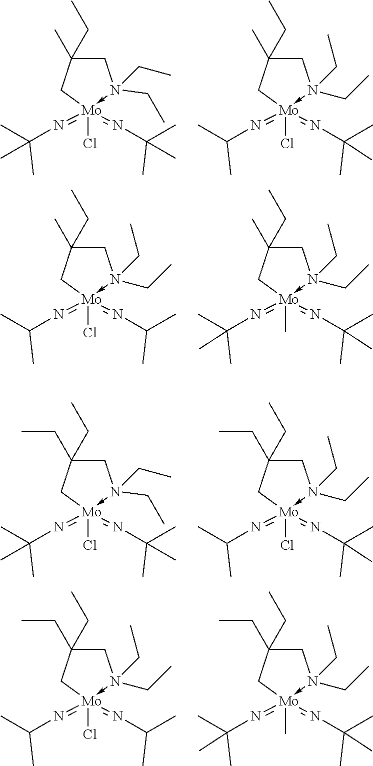

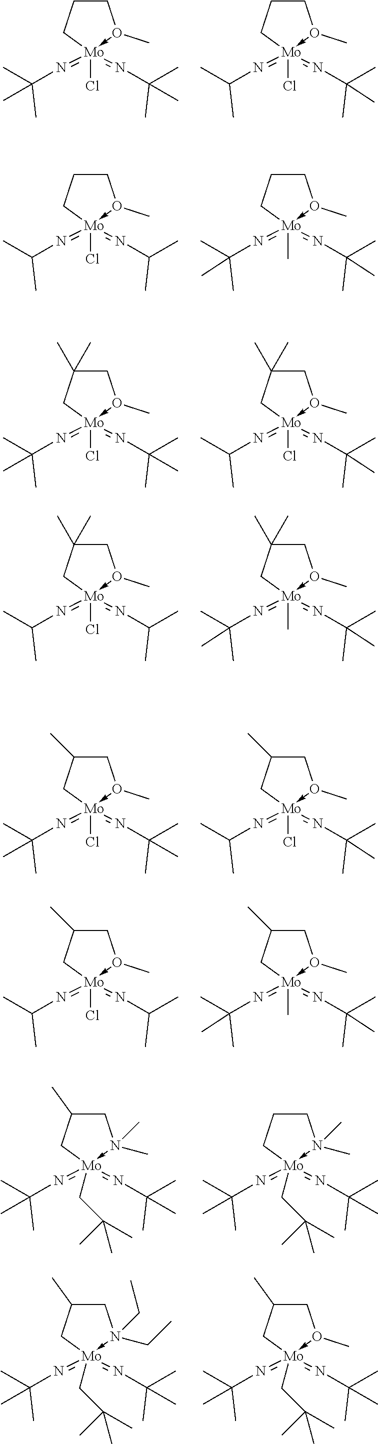

Specifically, the molybdenum compound according to an exemplary embodiment of the present invention may be selected from the following compounds:

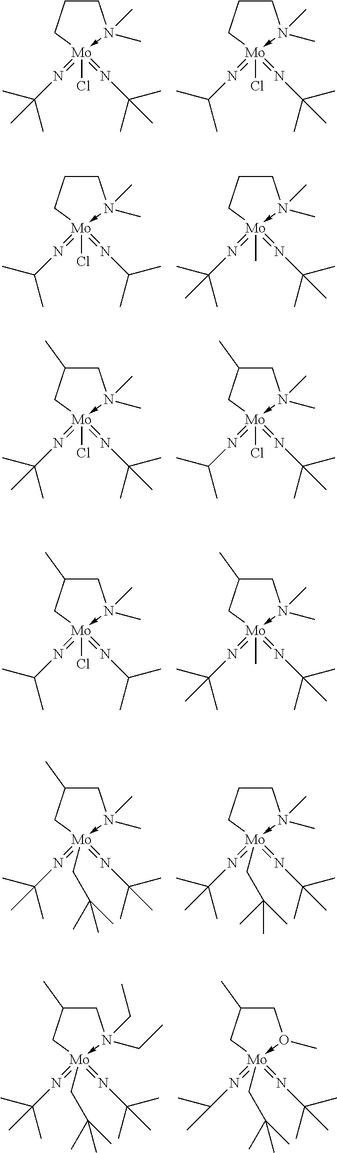

The present invention provides a method of producing a novel molybdenum compound, and specifically, the production method may include: reacting a compound represented by the following Chemical Formula 11 and a compound represented by the following Chemical Formula 12 to produce a molybdenum compound represented by the following Chemical Formula 1:

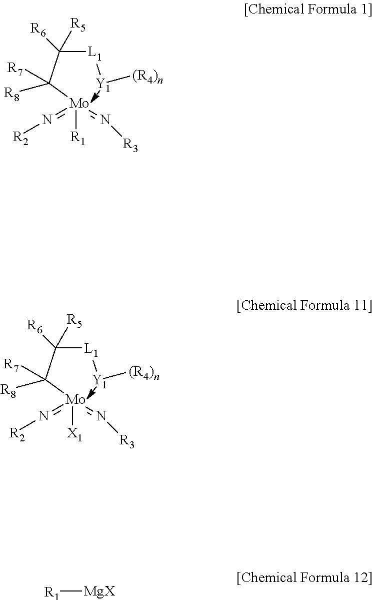

wherein
L₁ is C1-C5 alkylene;
Y₁ is N, O, or S;
R₁ is halogen, C1-C7 alkyl, C1-C7 alkoxy, monoC1-C7 alkylamino, or diC1-C7 alkylamino;
R₂ and R₃ are each independently C1-C7 alkyl;
R₄ to R₈ are each independently hydrogen or C1-C7 alkyl;
X and X₁ are each independently halogen; and
n is 1 or 2.

In the method of producing a molybdenum compound according to an exemplary embodiment of the present invention, the compound represented by Chemical Formula 12 may be used at a mole ratio of 1:1 to 1.2, based on the compound represented by Chemical Formula 11.

In the method of producing a molybdenum compound, a reaction temperature and a reaction time are not limited as long as they are the temperature and the time used in organic synthesis, and vary depending on the amounts of reaction materials and starting materials, but the reaction temperature may be −30 to 30° C., preferably −20 to 10° C., and more preferably −15 to 0° C. In addition, the reaction time may be 0.5 to 10 hours, specifically 1 to 9 hours, and more specifically 3 to 7 hours.

In addition, the method of producing a molybdenum compound according to an exemplary embodiment of the present invention may includes: reacting a compound represented by the following Chemical Formula 13 and a compound represented by the following Chemical Formula 14 to produce the compound represented by Chemical Formula 11:

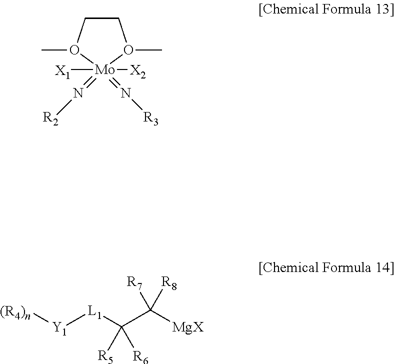

wherein
L₁ is C1-C5 alkylene;
Y₁ is N, O, or S;
R₂ and R₃ are each independently C1-C7 alkyl;
R₄ to R₈ are each independently hydrogen or C1-C7 alkyl; and
X, X₁, and X₂ are each independently halogen; and
n is 1 or 2.

In the method of producing a molybdenum compound according to an exemplary embodiment of the present invention, the compound represented by Chemical Formula 14 may be used at a mole ratio of 1:1 to 1.2, based on the compound represented by Chemical Formula 13.

In the method of producing a molybdenum compound, a reaction temperature and a reaction time are not limited as long as they are the temperature and the time used in organic synthesis, and vary depending on the amounts of reaction materials and starting materials, but the reaction temperature may be −5 to 60° C., preferably 5 to 50° C., and more preferably 15 to 30° C. In addition, the reaction time may be 3 to 20 hours, specifically 5 to 18 hours, and more specifically 7 to 16 hours.

In addition, the method of producing a molybdenum compound according to an exemplary embodiment of the present invention may be performed under a solvent, and the solvent may be any commonly used organic solvent, and for example, one or two or more selected from alcohol-based, alkane-based, aromatic-based, ether-based solvents, and the like. Specifically, the solvent may be one or two or more selected from methanol, ethanol, 1-propanol, 2-propanol, hexane, ether, toluene, and tetrahydrofuran, but is not limited thereto.

The reaction is completed after confirming that the starting materials are completely consumed, by NMR or the like. Thereafter, a process of separating and purifying a target may be performed by a common method such as an extraction process, a distillation process of solvent under reduced pressure, a recrystallization process, and tube chromatography.

Since the production method may show a high yield, it may be useful for a mass production process in a very economical way.

The present invention provides a molybdenum-containing composition for thin film deposition including the molybdenum compound according to an exemplary embodiment.

The molybdenum compound according to an exemplary embodiment of the present invention included in the molybdenum-containing composition for thin film deposition may be included at a concentration in a range which may be recognized by a person skilled in the art considering the film forming conditions of the thin film, the thickness and the properties of the thin film and the like.

The molybdenum-containing composition for thin film deposition may include one or two or more solvents selected from hydrocarbon-based solvents such as pentane, hexane, heptane, octane, decane, dodecane, ethylcyclohexane, propylcyclohexane, benzene, toluene, ethylbenzene, xylene, diethylbenzene, and ethyltoluene; alcohol solvents such as methanol, ethanol, propanol, isopropanol, butanol, and isobutanol; ether-based solvents such as diethylether, dipropylether, dibutylether, butylethylether, and tetrahydrofuran; and ester-based solvents such as methyl butyrate, ethyl butyrate, and propyl propionate.

The molybdenum-containing composition for thin film deposition according to the present invention includes the molybdenum compound of the present invention to show high volatility and reactivity, thereby providing a molybdenum-containing thin film having excellent quality.

In addition, the present invention provides a method of producing a molybdenum-containing thin film, and the production method is not particularly limited as long as it is allowed in a range which may be recognized by a person skilled in the art. For example, it may be performed by chemical vapor deposition (CVD), atomic layer deposition (ALD), metalorganic chemical vapor deposition (MOCVD), low pressure chemical vapor deposition (LPCVD), plasma enhanced chemical vapor deposition (PECVD), or plasma enhanced atomic layer deposition (PEALD).

Since the molybdenum compound according to an exemplary embodiment of the present invention may show excellent vapor pressure, be not easily decomposed even at a high temperature, and maintain a stable steam state even after vaporization, it may be effective for the deposition method described above.

Specifically, the production method may include: a) heating a substrate mounted in a chamber; and b) injecting a reaction gas and the molybdenum-containing composition for thin film deposition according to an exemplary embodiment of the present invention into the chamber to produce a molybdenum-containing thin film, wherein a temperature of the substrate may be maintained at 300 to 700° C.

The molybdenum-containing thin film according to the present invention may be a molybdenum-containing metal film, a molybdenum-containing oxide film, or a molybdenum-containing nitride film, but is not limited thereto.

In order to deposit the molybdenum-containing metal film according to the present invention, one or more selected from the group consisting of hydrogen (H₂), neutral nitrogen (N₂), and ammonia (NH₃) may be used as a reaction gas. In addition, in order to deposit the molybdenum-containing oxide thin film (Mo₂O₃, MoO₃) according to the present invention, one or more selected from the group consisting of water vapor (H₂O), oxygen (O₂), oxygen plasma (O₂ plasma), nitrogen oxide (NO, N₂O), nitrogen oxide plasma (N₂O plasma), oxygen nitride (N₂O₂), hydrogen peroxide water (H₂O₂), and ozone (O₃) may be used a reaction gas. In addition, in order to deposit the molybdenum-containing nitride thin film (MoN), one or more selected from the group consisting of ammonia (NH₃), ammonia plasma (NH₃ Plasma), hydrazine (N₂H₄), and nitrogen plasma (N₂ Plasma) may be used as a reaction gas.

In still another general aspect, a molybdenum-containing thin film produced by using the molybdenum compound according to an exemplary embodiment of the present invention is provided.

Since the molybdenum compound of the present invention has excellent volatility and reactivity, when a molybdenum-containing thin film is produced using the compound, the compound is relatively easily reduced to a molybdenum metal, and thus, a high-purity conductive molybdenum-containing thin film may be produced.

Hereinafter, the molybdenum compound, the method of producing the same, and the molybdenum-containing thin film including the same according to the present invention will be described in more detail by the specific examples.

However, the following examples are only a reference for describing the present invention in detail, and the present invention is not limited thereto and may be implemented in various forms. In addition, the terms used herein are only for effectively describing certain examples, and are not intended to limit the present invention.

Hereinafter, the examples for producing the molybdenum compound according to the present invention were performed under an inert argon or nitrogen atmosphere, using a glove box or a Schlenk linc.

### Example 1 Production of Compound 1

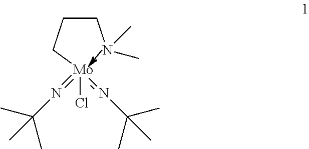

(t-butylN═)₂MoCl₂(DME) (11.6 g) and tetrahydrofuran (THF) (100 mL) were added to a 250 mL Schlenk flask, and 1 equivalent of DMAP-MgCl (3-Dimethylaminopropyl-magnesiumchloride) in THF was added dropwise at room temperature. After performing stirring at room temperature for 12 hours, the solvent was removed under reduced pressure. n-Hexane (100 mL) was added, filtration was performed, and the solvent was removed under reduced pressure. The product was distilled (114° C., 0.5 Torr) to obtain Compound 1 ((t-butylN═)₂MoCl(DMAP))(3 g) which was a yellow liquid (yield: 30%).
¹H NMR C₆D₆, 500 MHz): δ 2.50 (t, 2H, NCH₂), δ 2.37 (s, 6H, N(CH₃)₂), δ 1.93 (m, 2H, CCH₂C), δ 1.86 (m, 2H, CCCH₂), δ 1.32 (s, 18H, NC(CH₃)₃)

### Example 2 Production of Compound 2

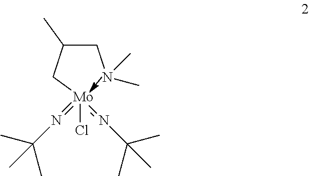

(t-butylN═)₂MoCl₂ (DME) (30 g) and tetrahydrofuran (THF) (100 mL) were added to a 250 mL Schlenk flask, and 1 equivalent of DMAMP-MgCl (3-dimethylamino-2-methylpropyl-magnesium chloride) in THF was added dropwise at room temperature. After performing stirring at room temperature for 12 hours, the solvent was removed under reduced pressure. n-Hexane (100 mL) was added, filtration was performed, and the solvent was removed under reduced pressure. The product was distilled (100° C., 0.1 Torr) to obtain Compound 2 ((t-butylN═)₂MoCl(DMAMP)) (7 g) which was a yellow liquid (yield: 25%).
¹H NMR(C₆D₆, 500 MHz): δ2.58 (s, 3H, N(CH₃)), δ2.55 (m, 1H, CCHC), δ2.19 (s, 3H, N(CH₃)), δ2.10 (m, 2H, NCH₂), δ2.10 (m, 1H, CCCH₂), δ1.51 (m, 1H, CCCH₂), δ1.34 (S, 9H, NC(CH₃)₃), δ1.31 (s, 9H, NC(CH₃)₃), δ0.90 (d, 3H, CCCH₃)

### Example 3 Production of Compound 3

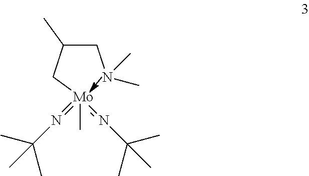

Compound 2 ((t-butylN═)₂MoCl (DMAMP)) (7 g) and toluene (50 mL) were added to a 250 mL Schlenk flask, and 1 equivalent of Me—MgI in ether was added dropwise at −10° C. After performing stirring at room temperature for 5 hours, the solvent was removed under reduced pressure. n-Hexane (50 mL) was added, filtration was performed, and the solvent was removed under reduced pressure. The product was distilled (80° C., 0.4 Torr) to obtain Compound 3 ((t-butylN═)₂MoMe(DMAMP))(2.2 g) which was a yellow liquid (yield: 38%).
¹H NMR(C₆D₆, 500 MHz): δ2.59 (t, 1H, CCHC), δ2.37 (s, 3H, N(CH₃)), δ2.03 (m, 2H, NCH₂), δ1.95 (m, 1H, CCCH₂), δ1.87 (s, 3H, N(CH₃)), δ1.44 (m, 1H, CCCH₂), δ1.39 (s, 9H, NC(CH₃)₃), δ1.37 (s, 9H, NC(CH₃)₃), δ1.01 (d, 3H, CCH₃), δ0.53 (s, 3H, MoCH₃)

### Example 4 Production of Compound 4

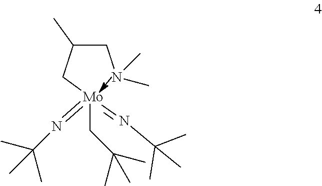

Compound 2 ((t-butylN═)₂MoCl (DMAMP)) (14 g) and ether (100 mL) were added to a 250 mL Schlenk flask, and 1 equivalent of (CH₃)₃CCH₂—MgCl (neopentyl-magnesium chloride) in THF was added dropwise at −10° C. After performing stirring at room temperature for 5 hours, the solvent was removed under reduced pressure. n-Hexane (100 mL) was added, filtration was performed, and the solvent was removed under reduced pressure. The product was distilled (140° C., 0.4 Torr) to obtain 3 g of Compound 4 ((t-butylN═)₂Mo(Neo-pentyl) (DMAMP)) which was a yellow liquid (yield: 20%).
¹H NMR(C₆D₆, 500 MHz): δ3.36 (s, 6H, N(CH₃)₂), δ2.57 (m, 1H, NCCH), δ2.10 (s, 2H, MoCH₂), δ1.96 (m, 1H, NCH₂), δ1.68 (m, 1H, NCH₂), δ1.37 (s, 18H, NC(CH₃)₃), δ1.26 (s, 9H, MoCC(CH₃)₃), δ1.18 (d, 3H, NCCCH₃)

A thermogravimetric analysis (TGA) method was used for measuring thermal stability, volatility, and decomposition temperature of Examples 1 to 3 of the present invention, and the weight of the product was measured with injection of nitrogen gas in an amount of 20 mL/min, while the product was heated to 500° C. at a rate of 10° C./min.

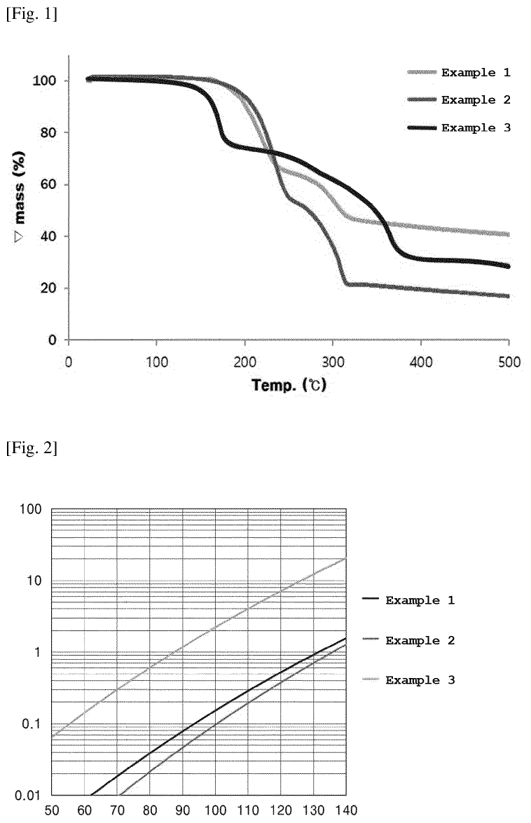

FIG. 1 shows results of TGA analysis of Examples 1 to 3, and in Example 1 (Compound 1), it was shown that decomposition started at 190° C., and since only 47 wt % of Example 1 (Compound 1) remained as a residue at 326° C., the thermal stability of Example 1 (Compound 1) was excellent.

Likewise, it was shown that the decomposition of Example 2 (Compound 2) and Example 3 (Compound 3) started at 153° C. and 180° C., respectively, and only 21 wt % and 32 wt % of Example 2 (Compound 2) and Example 3 (Compound 3) remained as residues at 317° C. and 389° C., respectively, and thus, the thermal stability of Example 2 (Compound 2) and Example 3 (Compound 3) was excellent.

In addition, FIG. 2 showed the results of analysis of vapor pressure of Examples 1 to 3, and it was shown that the molybdenum compound of Examples 1 to 3 of the present invention had excellent vapor pressure from the vapor pressure graph.

It is shown that the molybdenum compound of the present invention has a specific structure and a specific functional group, thereby showing more improved vapor pressure and thermal stability, and when a molybdenum-containing thin film is produced using the compound, the film may have excellent uniformity and step coverage to show more improved electrical properties.

Hereinabove, although the present invention has been described by specific matters, Examples, and Comparative Examples, they have been provided only for assisting in the entire understanding of the present invention. Therefore, the present invention is not limited to the above Examples. Various modifications and changes may be made by those skilled in the art to which the present invention pertains from this description.

Therefore, the spirit of the present invention should not be limited to the above-described exemplary embodiments, and the following claims as well as all modifications equal or equivalent to the claims are intended to fall within the scope and spirit of the invention.

1. A molybdenum compound represented by the following Chemical Formula 1: 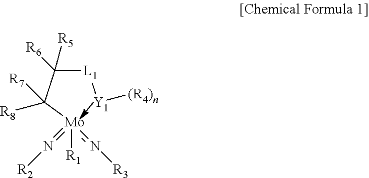
wherein
L₁ is C1-C5 alkylene;
Y₁ is N, O, or S;
R₁ is halogen, C1-C7 alkyl, C1-C7 alkoxy, monoC1-C7 alkylamino, or diC1-C7 alkylamino;
R₂ and R₃ are each independently C1-C7 alkyl;
R₄ to R₈ are each independently hydrogen or C1-C7 alkyl; and
n is 1 or 2.

2. The molybdenum compound of claim 1, wherein in Chemical Formula 1,
L₁ is C1-C3 alkylene;
Y₁ is N, O, or S;
R₁ is halogen, C1-C5 alkyl, or C1-C5 alkoxy;
R₂ and R₃ are each independently C1-C5 alkyl;
R₄ to R₈ are each independently hydrogen or C1-C5 alkyl; and
n is 1 or 2.

3. The molybdenum compound of claim 1, wherein in Chemical Formula 1,
L₁ is C1-C3 alkylene;
Y₁ is N or O;
R₁ is halogen, C1-C5 alkyl, or C1-C5 alkoxy;
R₂ and R₃ are each independently branched C3-C5 alkyl;
R₄ to R₈ are each independently hydrogen or linear C1-C3 alkyl; and
n is 1 or 2.

4. The molybdenum compound of claim 1, wherein the molybdenum compound is represented by the following Chemical Formula 2: 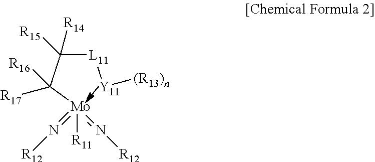
wherein
L₁₁ is C1-C5 alkylene;
Y₁₁ is N, O, or S;
R₁₁ is halogen, C1-C7 alkyl, C1-C7 alkoxy, monoC1-C7 alkylamino, or diC1-C7 alkylamino;
R₁₂ is C1-C7 alkyl;
R₁₃ to R₁₇ are each independently hydrogen or C1-C7 alkyl; and
n is 1 or 2.

5. The molybdenum compound of claim 4, wherein in Chemical Formula 2,
L₁₁ is C1-C3 alkylene;
Y₁₁ is N or O;
R₁₁ is halogen, C1-C5 alkyl, or C1-C5 alkoxy;
R₁₂ is branched C3-C5 alkyl;
R₁₃ to R₁₇ are each independently hydrogen or linear C1-C3 alkyl; and
n is 1 or 2.

6. The molybdenum compound of claim 1, wherein the molybdenum compound is selected from the group consisting of the following compounds:

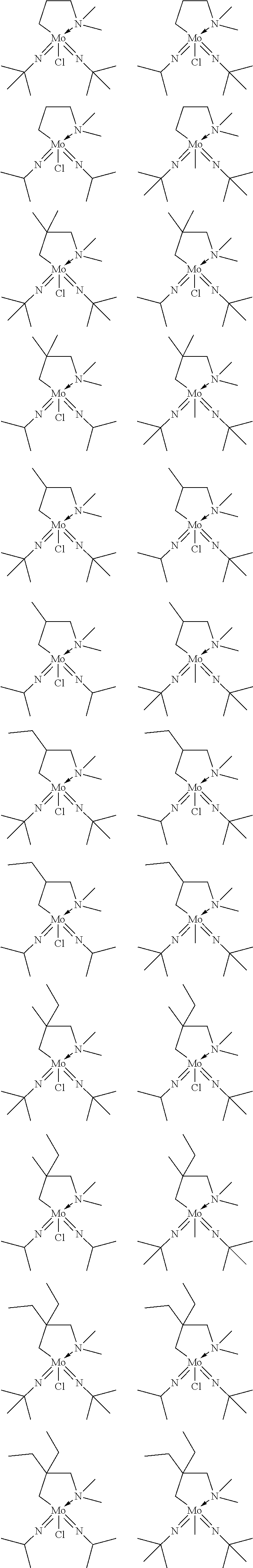

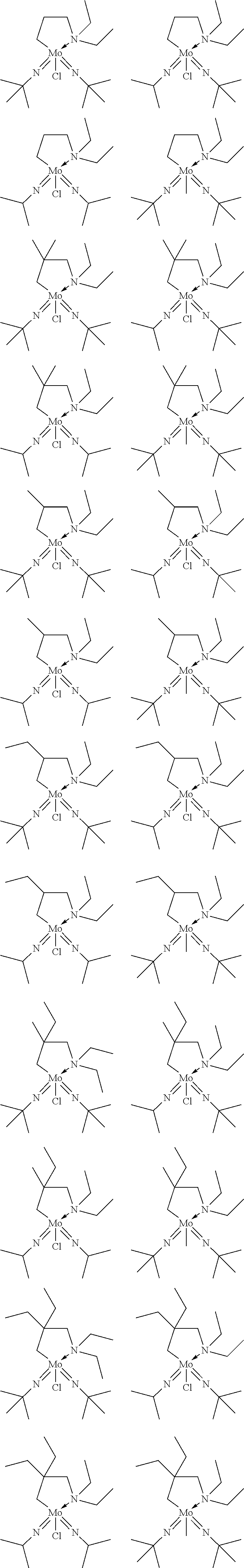

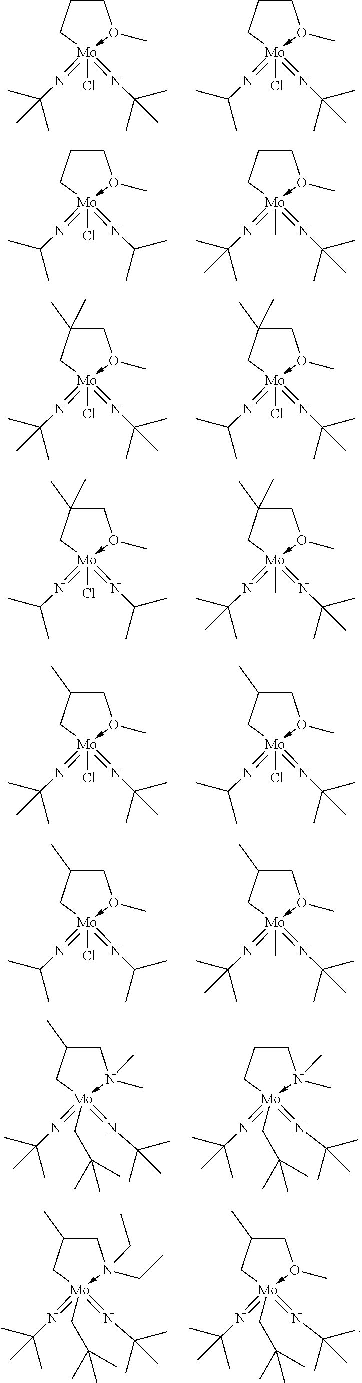

7. A method of producing a molybdenum compound, the method comprising:
reacting a compound represented by the following Chemical Formula 11 and a compound represented by the following Chemical Formula 12 to produce a molybdenum compound represented by the following Chemical Formula 1: 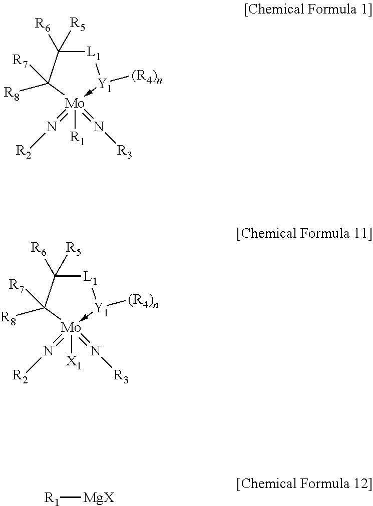
wherein
L₁ is C1-C5 alkylene;
Y₁ is N, O, or S;
R₁ is halogen, C1-C7 alkyl, C1-C7 alkoxy, monoC1-C7 alkylamino, or diC1-C7 alkylamino;
R₂ and R₃ are each independently C1-C7 alkyl;
R₄ to R₈ are each independently hydrogen or C1-C7 alkyl;
X and X₁ are each independently halogen; and
n is 1 or 2.

8. The method of producing a molybdenum compound of claim 7, wherein reacting a compound represented by the following Chemical Formula 13 and a compound represented by the following Chemical Formula 14 to produce the molybdenum compound represented by Chemical Formula 11 is included: 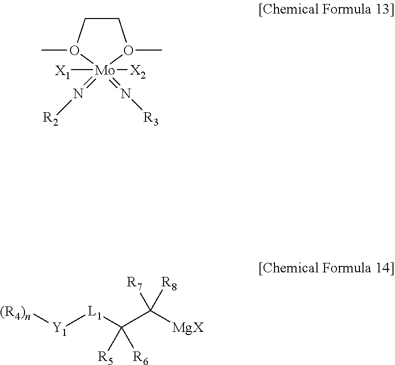
wherein
L₁ is C1-C5 alkylene;
Y₁ is N, O, or S;
R₂ and R₃ are each independently C1-C7 alkyl;
R₄ to R₈ are each independently hydrogen or C1-C7 alkyl;
X, X₁, and X₂ are each independently halogen; and
n is 1 or 2.

9. A molybdenum-containing composition for thin film deposition comprising the molybdenum compound of claim 1.

10. A method of producing a molybdenum-containing thin film, the method comprising:
a) heating a substrate mounted in a chamber; and
b) injecting a reaction gas and a molybdenum-containing composition comprising the molybdenum compound of claim 1 into the chamber to produce a molybdenum-containing thin film.

11. The method of producing a molybdenum-containing thin film of claim 10, wherein the substrate is maintained at 300° C. to 700° C.

12. A molybdenum-containing thin film produced using the molybdenum compound of claim 1.
